(19) United States
(12) Patent Application Publication
(10) Pub. No.: US 2010/0159680 A1
(43) Pub. Date: Jun. 24, 2010

(54) Method for Manufacturing Semiconductor Device

(76) Inventor: Chung Kyung JUNG, Anyang-si (KR)

Correspondence Address: THE LAW OFFICES OF ANDREW D. FORTNEY, PH.D., P.C., 215 W FALLBROOK AVE SUITE 203, FRESNO, CA, 93711, US

(21) Appl. No.: 12/617,594

(22) Filed: Nov. 12, 2009

(30) Foreign Application Priority Data
Dec. 18, 2008 (KR) 10-2008-0129147

(51) Int. Cl. H01L 21/265

(52) U.S. Cl. 438/514; 257/E21.334

(57) ABSTRACT

A method for manufacturing a semiconductor device is disclosed. The method includes the steps of forming a nitride film on a semiconductor substrate, forming a photoresist pattern on the nitride film, the photoresist pattern exposing a portion of the semiconductor substrate, implanting in a portion of the semiconductor substrate using the photoresist pattern as a mask, removing the photoresist pattern by ashing and/or stripping, washing the resulting structure to remove photoresist pattern splinters, fragments or particles on the nitride film, and removing the nitride film by wet etching.

### CROSS REFERENCE TO RELATED APPLICATION

This application claims the benefit of the Patent Korean Application No. 10-2008-0129147, filed on 18 Dec. 2008, which is hereby incorporated by reference as if fully set forth herein.

### BACKGROUND OF THE DISCLOSURE

1. Field of the Disclosure

The present invention relates to semiconductor devices, and more particularly, to a method for manufacturing a semiconductor device, which enables effective removal of photoresist residue.

2. Discussion of the Related Art

As technologies to make semiconductor devices develop, CMOS FETs generally include a polysilicon gate (hereinafter, a “polygate”) and dopants such as phosphorus (P), indium (In), boron (B), and so on are used for NMOS or PMOS transistors.

In the case of an implanting step in a process for manufacturing a semiconductor device, the dopant is implanted into a small area heavily following reduction of a pitch size of the semiconductor device. For implanting into the small area, a photoresist pattern formed by photolithography is used as an ion injection or implantation mask. The implanting step is performed using the photoresist pattern as an ion injection or implantation mask, for implanting a heavy dose of impurities into the polygate. In the implanting step, the outer portion of the photoresist pattern may harden as a result of the high concentration of impurity ions.

FIG. 1A illustrates a cross-section showing the implanting step of a related art semiconductor device. FIG. 1B illustrates a cross-section of a photoresist pattern of which an outside portion is hardened by the implanting step shown in FIG. 1A. FIG. 1C is a picture showing residue formed on a semiconductor device in a washing step for removing a photoresist pattern used as a mask in an ion implantation process.

Referring to FIG. 1A, a gate oxide film 120 and a polysilicon layer 130 are formed on a substrate 110 having a device isolation film 115 formed thereon in succession. Then, a photoresist pattern 135 is formed on the polysilicon layer 130, and an implanting step is performed using the photoresist pattern 135 as a mask for injecting impurity ions into the polysilicon layer 130.

Referring to FIG. 1B, the photoresist pattern 135-1 having an outside portion 137 hardened in the implanting step shown in FIG. 1A is not easily removed by a following washing step. Moreover, as the hardness of the outside portion 137 differs from an inside portion 138 of the photoresist pattern 135-1, a weak portion 139 of the photoresist pattern may burst in a subsequent washing step. This phenomenon is sometimes called a “PR popping” effect.

Referring to FIG. 1C, a splinter or fragment 140 of the photoresist caused by the PR popping effect can stay on the gate 130, and the splinter or fragment 140 can act as an etch barrier or mask in forming a gate pattern, impairing a quality of the semiconductor device.

### SUMMARY OF THE DISCLOSURE

Accordingly, the present invention is directed to a method for manufacturing a semiconductor device.

An object of the present invention is to provide a method for manufacturing a semiconductor device that can solve problems caused by hardening of a photoresist pattern from an implanting process (e.g., at a high dose) in a polysilicon layer for a MOSFET. The present method can improve the manufacturing yield and the reliability of the semiconductor device.

Additional advantages, objects, and features of the disclosure will be set forth in part in the description which follows and in part will become apparent to those skilled in the art upon examination of the following or may be learned from practice of the invention. The objectives and other advantages of the invention may be realized and attained by the structure(s) particularly pointed out in the written description and claims hereof as well as the appended drawings.

To achieve these objects and other advantages and in accordance with the purpose(s) of the invention, as embodied and broadly described herein, a method for manufacturing a semiconductor device can include the steps of forming a nitride film on a semiconductor substrate, forming a photoresist pattern on the nitride film, the photoresist pattern exposing a portion of the semiconductor substrate, implanting ions in a portion of the semiconductor substrate using the photoresist pattern as a mask, removing the photoresist pattern by at least one of asking and stripping, and removing the nitride film and photoresist splinters, fragments or particles on the nitride film by wet etching.

In another aspect of the present invention, a method for manufacturing a semiconductor device can include the steps of forming a gate oxide film and a polysilicon film on a semiconductor substrate, forming a nitride film on the polysilicon film, performing photolithography to form a photoresist pattern on the nitride film, implanting ions using the photoresist pattern as a mask, removing the photoresist pattern using at least one of asking and stripping, and removing the nitride film and photoresist splinters, fragments or particles on the nitride film by wet etching.

Thus, the present method for manufacturing a semiconductor device can improve the fabrication yield and the reliability of the semiconductor device by depositing a nitride film on a material in which ions are to be implanted, and removing photoresist pattern splinters, fragments or particles (which may be caused by the PR popping effect) together with the nitride film using a H₃PO₄ solution.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle(s) of the disclosure. In the drawings:

FIG. 1A illustrates a cross-section showing an implanting step in a process for making a related art semiconductor device.

FIG. 1B illustrates a cross-section of a photoresist pattern of which an outside portion is hardened by the implanting step in FIG. 1A.

FIG. 1C illustrates residue remaining from a washing step to remove a photoresist pattern (e.g., such as that illustrated in FIG. 1A.

FIGS. 2A-2G illustrate cross-sections of exemplary structures showing the steps of an exemplary method for manufacturing a semiconductor device in accordance with various embodiments of the present invention.

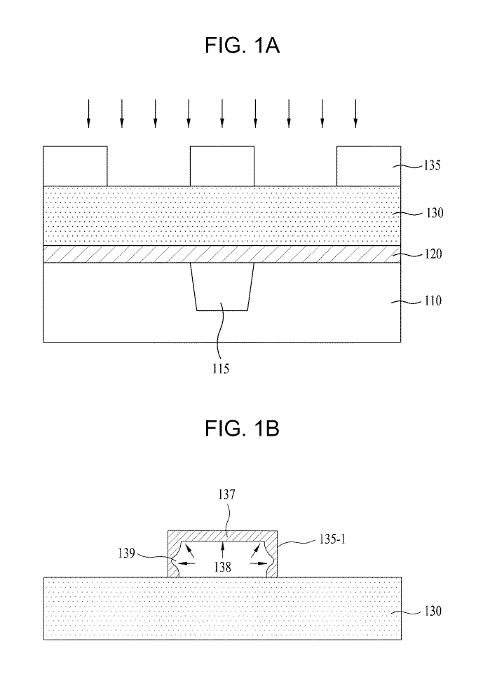

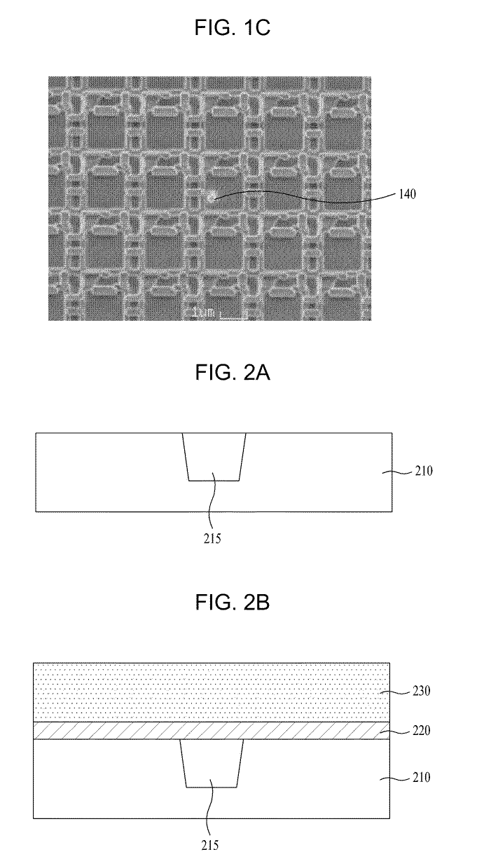

### DESCRIPTION OF SPECIFIC EMBODIMENTS

Reference will now be made in detail to specific embodiments of the present invention, examples of which are illustrated in the accompanying drawings. Wherever possible, the same reference numbers will be used throughout the drawings to refer to the same or like parts.

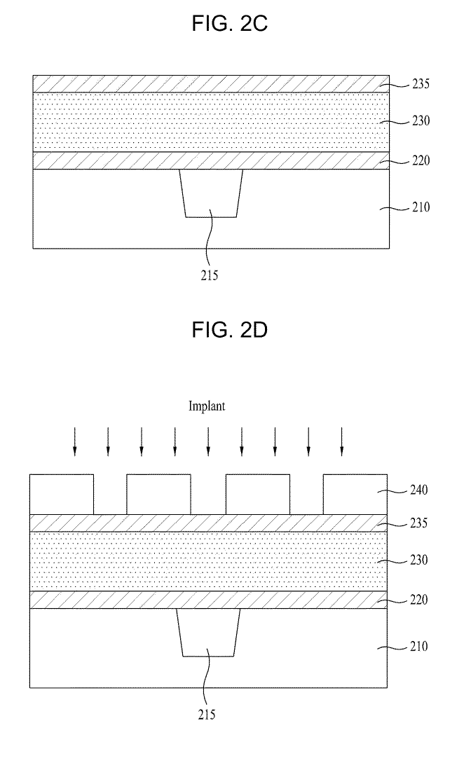

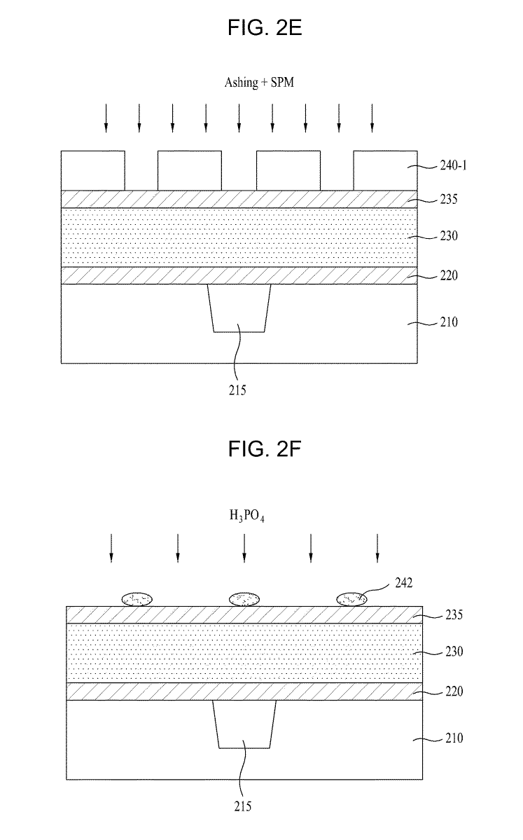

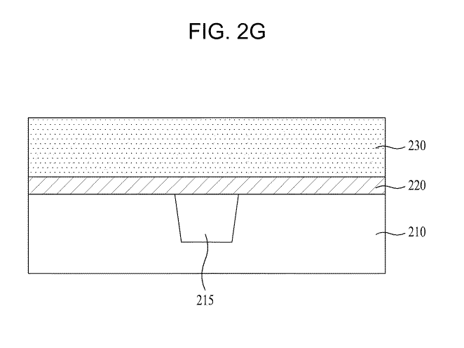

FIGS. 2A-2G illustrate cross-sections of exemplary structures showing the steps of an exemplary method for manufacturing a semiconductor device in accordance with various embodiments of the present invention.

Referring to FIG. 2A, a device isolation film 215 is formed in a semiconductor substrate 210 to define a device isolation (e.g., field) region and an active region. For an example, the device isolation film 215 may be formed by STI (Shallow Trench Isolation) or R-LOCOS (Recessed-Local Oxidation of Silicon).

Referring to FIG. 2B, a gate oxide film 220 and a polysilicon film 230 are formed in succession on the semiconductor substrate 210 having the device isolation film 215 formed therein. For an example, the gate oxide film 220 may be formed on the semiconductor substrate 210 by wet or dry thermal oxidation or by chemical vapor deposition (CVD), and the polysilicon film 230 may be formed on the semiconductor substrate 210 by CVD (e.g., from a silicon precursor gas such as silane).

Though FIG. 2B shows a structure having only a stack of the gate oxide film 220 and the polysilicon film 230, in a case of a flash memory device, the stack may comprise a tunnel oxide film, a first polysilicon film (for a floating gate), a gate oxide film or an ONO film (Oxide-Nitride-Oxide film), and a second polysilicon film (e.g., for a control gate), formed in succession.

Referring to FIG. 2C, a nitride film 235 is formed on the polysilicon film 230. For an example, a silicon nitride (SiN) film 235 may be formed by CVD using NH₃ gas (and, optionally, N₂ gas) and SiH₄ gas.

Referring to FIG. 2D, a photoresist pattern 240 is formed on the nitride film 235 by photolithography. The photoresist pattern 240 is patterned to expose one or more portions of the silicon nitride film 235 (e.g., in areas where the polysilicon film 235 is to be implanted).

Generally, the nitride film 240 is relatively thin in comparison with the polysilicon film 235. For example, if the polysilicon film 235 has a thickness of 1500-2500 Å, then the nitride film 240 may have a thickness of 50-200 Å. Thus, the ratio of the thicknesses of the nitride film 240 to the polysilicon film 235 may be from about 1:10 to about 1:50 (or any range of values therein).

Then, an ion implantation is performed using the photoresist pattern 240 as a mask, to inject impurities at a high dose (for an example, over 1E15 atoms/cm²) into the exposed areas of the nitride film 240. For an example, one or more of phosphorous (P) and/or indium (In), or boron (B), can be injected at a dose of 1E15 atoms/cm²˜1E20 atoms/cm². In the implantation shown in FIG. 2D, an outside portion of the photoresist pattern 240 is hardened.

Referring to FIG. 2E, at least one process selected from plasma asking and stripping is performed to remove the photoresist pattern. In one embodiment, both plasma ashing and stripping are performed.

In the plasma ashing process, the photoresist pattern 240 is removed using an oxygen plasma, which may use O₂ and/or O₃ gas. Basically, since the photoresist pattern 240 comprises a carbon-based polymer (e.g., a hydrocarbon, a polyacrylate or polymethacrylate, etc.), oxygen atoms react with the photoresist pattern 240 quickly, to form volatile reaction products (e.g., carbon monoxide [CO], carbon dioxide, and/or water [H₂O]).

In the stripping, the photoresist is removed by using sulfuric acid H₂SO₄ and hydrogen peroxide H₂O₂ (generally as an aqueous mixture). In one embodiment, a mixing ratio of the sulfuric acid H₂SO₄ and the hydrogen peroxide H₂O₂ is from 2:1 to 10:1 (e.g., 6:1).

During the plasma ashing and/or the stripping to remove the photoresist pattern 240-1 (which may have an outside portion hardened by ion implantation), a PR popping effect may take place.

Referring to FIG. 2F, there may be photoresist splinters, fragments or particles 242 present on the nitride film 235 due to the PR popping effect.

Next, the nitride film 235 is wet etched using H₃PO₄ solution, to remove the nitride film 235. The H₃PO₄ solution may be a concentrated or dilute aqueous solution (e.g., from about 25% to 85% by weight H₃PO₄), and the H₃PO₄ solution may be heated (e.g., to a temperature of from 50° C. to 100° C.) prior to use. In this instance, the photoresist splinters, fragments or particles 242 can be removed together (e.g., simultaneously) with the nitride film 235.

For an example, if the nitride film is subjected to an isotropic etching using the H₃PO₄ solution, the splinters, fragments or particles 242 adsorbed to the nitride film 235 are detached before, during or following removal of the nitride film 235. The splinters, fragments or particles 242 thus detached can be removed by QDR (Quick Dump Rinse). In the QDR process, the detached splinters, fragments or particles 242 are further washed off or removed using DIW (De-Ionized Water), which may be sprayed onto the wafers or which may be added to the QDR chamber (optionally with sonic or megasonic energy applied thereto) and quickly dumped to remove the DIW and any photoresist particles therein.

FIG. 2G illustrates a cross-section showing the nitride film 235 and the photoresist splinters, fragments or particles 242 removed from etching and cleaning the nitride film 235. By wet etching the nitride film 235 with H₃PO₄ solution, the photoresist splinters, fragments or particles 242 on the nitride film 235 (due to the PR popping effect or other cause) can be removed effectively.

Though FIGS. 2A to 2G illustrate only a method for removing the photoresist splinters, fragments or particles that may arise from the PR popping effect resulting from implanting a high dose of ions into a polysilicon layer of the semiconductor device, technical aspects of the present invention are not limited to this.

A nitride film is formed on a semiconductor substrate (or a polysilicon film formed over the semiconductor substrate), and a photoresist pattern is formed on the nitride film, which exposes a portion of the semiconductor substrate (or the nitride film). Then, ion implantation is performed on the semiconductor substrate using the photoresist pattern as a mask. If the ion implantation is performed using the photoresist pattern, the photoresist pattern can be hardened. Then, using at least one of ashing and stripping, the photoresist pattern can be substantially removed. If the photoresist pattern hardened after the ion implantation is removed by ashing and stripping, the PR popping effect can take place.

Then, the nitride film is wet etched using an aqueous H₃PO₄ solution to remove the nitride film together with the photoresist splinters, fragments or particles that may be formed due to the PR popping effect.

In conclusion, a first feature of the present invention flows from deposition of a nitride film on a material into which ion implantation is to be performed. A second feature of the present invention concerns removing the photoresist pattern splinters, fragments or particles (which may be formed due to the PR popping effect) together with the nitride film using a H₃PO₄ solution. The semiconductor device manufactured by this method can have improved yield and reliability.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A method for manufacturing a semiconductor device comprising:
forming a nitride film on a semiconductor substrate;
forming a photoresist pattern on the nitride film, the photoresist pattern exposing a portion of the semiconductor substrate;
implanting ions into a portion of the semiconductor substrate using the photoresist pattern as a mask;
removing the photoresist pattern using at least one of asking and stripping; and
removing the nitride film and photoresist splinters, fragments or particles on the nitride film by wet etching.

2. The method as claimed in claim 1, wherein forming a nitride film comprises chemical vapor deposition (CVD) using NH₃ gas and/or SiH₄ gas.

3. The method as claimed in claim 1, wherein implanting ions includes injecting phosphorous (P), indium (In), or boron (B) at a dose of 1E15 atoms/cm²˜1E20 atoms/cm².

4. The method as claimed in claim 1, wherein removing the photoresist pattern includes the steps of:
ashing the photoresist pattern by using oxygen plasma using O₂ gas, and
stripping the asked photoresist pattern using H₂SO₄ and H₂O₂.

5. The method as claimed in claim 1, wherein wet etching the nitride film comprises using H₃PO₄ solution.

6. A method for manufacturing a semiconductor device comprising:
forming a gate oxide film and a polysilicon film on a semiconductor substrate;
forming a nitride film on the polysilicon film;
performing photolithography to form a photoresist pattern on the nitride film;
implanting ions using the photoresist pattern as a mask;
removing the photoresist pattern using at least one of ashing and stripping; and
removing the nitride film and photoresist splinters, fragments or particles on the nitride film by wet etching.

7. The method as claimed in claim 6, wherein removing the photoresist pattern includes:
plasma asking the photoresist pattern using an oxygen plasma comprising O₂ gas, and stripping the plasma asked photoresist pattern using a solution of H₂SO₄ and H₂O₂.

8. The method as claimed in claim 6, wherein implanting ions includes injecting phosphorous (P), indium (In), or boron (B) into the polysilicon film at a dose of 1E15 atoms/cm²˜1E20 atoms/cm².

9. The method as claimed in claim 6, wherein removing the nitride film and photoresist splinters, fragments or particles includes:
isotropically etching the nitride film using a H₃PO₄ solution, and
washing the photoresist splinters, fragments or particles with DIW (De-Ionized Water).

10. The method as claimed in claim 6, wherein removing the nitride film and photoresist splinters, fragments or particles includes the step of wet etching the nitride film using a H₃PO₄ solution.

11. A method for manufacturing a semiconductor device comprising:
forming a nitride film on a semiconductor substrate;
forming a photoresist pattern on the nitride film, the photoresist pattern exposing portions of the nitride film;
implanting ions into portions of the semiconductor substrate using the photoresist pattern as a mask;
removing the photoresist pattern by asking and/or stripping; and
removing the nitride film and photoresist particles by wet etching the nitride film and wet cleaning the semiconductor substrate.

12. The method as claimed in claim 11, wherein forming a nitride film comprises chemical vapor deposition (CVD) using NH₃ gas and SiH₄ gas.

13. The method as claimed in claim 11, wherein implanting ions includes injecting phosphorous (P), indium (In), or boron (B) at a dose of 1E15 atoms/cm²˜1E20 atoms/cm².

14. The method as claimed in claim 11, wherein forming the photoresist pattern comprises performing photolithography on a photoresist layer on the nitride film.

15. The method as claimed in claim 11, wherein removing the photoresist pattern includes asking the photoresist pattern using an oxygen plasma.

16. The method as claimed in claim 15, wherein removing the photoresist pattern further includes stripping the asked photoresist pattern using a solution of H₂SO₄ and H₂O₂.

17. The method as claimed in claim 11, wherein wet etching the nitride film comprises using a H₃PO₄ solution.

18. The method as claimed in claim 17, wherein removing the photoresist particles includes washing the photoresist splinters, fragments or particles with DIW (De-Ionized Water).

19. The method as claimed in claim 11, wherein the semiconductor substrate comprises a polysilicon layer under the nitride film, and the ions are implanted into portions of the polysilicon layer.
